(19) United States
(12) Patent Application Publication
(10) Pub. No.: US 2003/0186521 A1
(43) Pub. Date: Oct. 2, 2003

(54) Method of transferring thin film functional material to a semiconductor substrate or optimized substrate using a hydrogen ion splitting technique

(76) Inventors: Francis J. Kub, Arnold, MD (US); Karl D. Hobart, Upper Marlboro, MD (US)

Correspondence Address: NAVAL RESEARCH LABORATORY, ASSOCIATE COUNSEL (PATENTS), CODE 1008.2, 4555 OVERLOOK AVENUE, S.W., WASHINGTON, DC, 20375-5320, US

(21) Appl. No.: 10/113,633

(22) Filed: Mar. 29, 2002

(51) Int. Cl. H01L 21/22

(52) U.S. Cl. 438/558

(57) ABSTRACT

A method for making devices having either a substrate with CMOS or GaAs circuitry or which is optimized for a particular property is provided. In one alternative, a film layer of thin film functional material is grown on a large diameter growth substrate. One or more protective layers may be deposited on the surface of the growth substrate before the thin film functional material is deposited. Hydrogen is implanted to a selected depth within the growth substrate or within a protective layer to form a hydrogen ion layer. The growth substrate and associated layers are bonded to a second substrate. The layers are split along the hydrogen ion implant and the portion of the growth substrate and associated layer that is on the side of the ion layer away from the second substrate is removed.

### BACKGROUND OF THE INVENTION

1. Field of the Invention

The present invention relates to the manufacture of layered semiconductor materials and more particularly, to a method for manufacturing a layered semiconductor material by transferring a thin film functional material from a growth substrate to an application substrate using hydrogen ion splitting technology.

2. Related Art

There is interest in the art in the fabrication of improved electronic devices such as piezoelectric transducers, piezoelectric actuators, decoupling capacitors, tunable microwave capacitors, microwave resonators, electro-optical modulators, electro-optical switches, semi-conductor optical amplifiers, second harmonic generation un-cooled infrared detectors, cryogenic infrared detectors, photodetectors, lasers, photo emitting laterally electrically FETs, vertical electrical conducting material for lasers, and LEDs. More specifically, CMOS (complementary metal-oxide semiconductor) technology is used in the manufacture of many of the transistors used in computer microchips. In addition to requiring only very small amounts of space, CMOS circuitry is very power efficient. This makes CMOS circuitry particularly attractive for use in battery-powered devices such as portable computers, in addition to many other applications. GaAs circuitry is of similar value.

A substrate comprised of silicon or GaAs and having CMOS or GaAs circuitry is often used in the fabrication of these devices. Additionally, a substrate comprised of a material such as glass, quartz, poly-SiC, semi-insulating GaAs, diamond, or sapphire, which has been optimized for a specific property or properties can be used when desired. These optimized substrates are often optimized for properties such as thermal expansion coefficient, thermal conductivity, and low microwave loss, i.e. insulating.

The utility of semi-conductor circuitry containing substrates and optimized substrates alike can be improved by adding a thin film of appropriate “functional” material on top of each respective substrate. The number of devices that can be fabricated with the substrates will be greatly increased, depending upon the transfer material or materials added.

The thin film “functional” materials which might be transferred to a semiconductor substrate include photoelectric, piezoelectric, pyroelectric, electro-optical, wave guide, nonlinear optical, photorefractive, wide band gap materials. Suitable functional thin film materials for optimized substrate applications include PZT, SrBaTiO₃, PLZT, LiNbO₂, SiGe, GaAs, CdTe/HgCdTe, ZnO and GaN. Such thin film materials, because of their special qualities, can be utilized in the devices herein.

To obtain a high quality thin film material, the material is typically grown on a substrate at a growth temperature or annealing temperature of 500° C. to 1000° C. The high growth temperature is required to assure a high quality thin film material. However, the highest temperature that a substrate containing CMOS integrated circuit technology can withstand, especially when metal interconnectors between circuitry layers are in place, is typically 450° C. to 500° C. Therefore, it is generally not possible to obtain the best quality thin film material by growing the material directly on a CMOS substrate. Growing a thin film functional material on an optimized substrate presents similar problems.

An optimal solution is to grow the thin film material on a first, or growth, substrate, such as silicon, that can withstand the increased temperatures and then transfer the thin film material after it is grown to a second, semiconductor or optimized, substrate for use therewith.

However, there have been problems with isolating, and then transferring, the thin film layer. If the growth substrate is chemically or plasma etched away, mechanically or thinned using lapping or grinding, the risk of damage to the thin film layer during this process is considerable. Further, some growth substrate materials are very expensive, and elimination of the substrate to isolate the thin film layer is cost prohibitive. Finally, the use of etching, grinding and like processes to eliminate the growth substrate make the creation of a smooth separation surface difficult.

There have been attempts in the prior art to address this issue.

Prior art of interest includes U.S. Pat. No. 6,054,370 to Doyle; U.S. Pat. No. 5,994,207 to Henley et al.; U.S. Pat. No. 5,993,677 to Biasse et al.; U.S. Pat. No. 5,966,620 to Sakaguchi et al.; U.S. Pat. No. 5,877,070 to Goesele et al.; U.S. Pat. No. 5,882,987 to Srikrishnan; U.S. Pat. No. 5,654,583 to Okuno et al.; and U.S. Pat. No. 5,391,257 to Sullivan et al.

The Doyle, Henley et al., Biasse, Sakaguchi et al., and Goesele et al. patents each disclose methods which utilize, to some extent, ion implantation, wafer bonding, and layer splitting for the transfer of semiconductor films to second substrates. For example, the Biasse et al. patent discloses a method for transferring a thin film from an initial substrate to a final substrate by joining the thin film to a handle substrate, cleaving the initial substrate, joining the thin film to a final substrate, and cleaving the handle substrate. The Goesele et al. patent discloses a method of transferring thin monocrystalline layers to second substrates at lower temperatures than previously possible. The Srikrishnan patent discloses a method for the production of monocrystalline films using an etch stop layer. The Okuno et al. patent discloses a method for direct bonding different semiconductor structures in order to form a unified semiconductor device. The Sullivan et al. patent discloses a method for transferring thin films, which utilizes etch stop layers.

### SUMMARY OF THE INVENTION

In accordance with the invention, a method for transferring a thin film material from a growth substrate to an application substrate is provided.

In one embodiment, a method for making a thin film semiconductor device is provided, the method comprising the steps of: depositing at least one protective layer on one surface of a growth substrate; growing, optionally, a film layer of thin film functional material on the at least one protective layer, said functional material comprising a material selected from the group consisting of photoelectric, piezoelectric, pyroelectric, electro-optical, wave guide, nonlinear optical, photorefractive, and wide band gap materials; implanting hydrogen to a selected depth within the growth substrate or within the at least one protective layer to form a hydrogen ion layer so as to divide the material having the growth substrate and the at least one protective layer into distinct portions; bonding the growth substrate including the at least one protective layer and the thin film layer to a second substrate comprising silicon or GaAs and having CMOS or GaAs circuitry; splitting the material having the growth substrate and the at least one protective layer along the implanted ion layer and removing the portion of the material which is on the side of the ion layer away from the substrate having CMOS or GaAs circuitry.

Preferably, the growth substrate is comprised of a material selected from a group consisting of silicon, GaAs, quartz, and sapphire. Advantageously, the growth substrate comprises silicon.

Advantageously, the growth substrate comprises silicon; the at least one protective layer comprises an oxide layer, an adhesion layer, and a barrier layer; and the method further comprises the steps of depositing the oxide layer on the silicon substrate; depositing the adhesion layer on the oxide layer; and depositing the barrier layer on the adhesion layer for isolating the thin film layer. Preferably, the adhesion layer is comprised of titanium, and the barrier layer comprises a material selected from a group consisting of platinum and iridium.

Alternatively, the at least one protective layer comprising MgO.

Preferably, the thin film functional material is comprised of a material selected from a group consisting of PZT, SrBaTiO₃, PLZT, LiNbO₂, SiGe, GaAs, CdTe/HgCdTe, ZnO and GaN.

Advantageously, the thin film functional material layer is annealed for strengthening and tempering the thin film layer at a temperature of about 600° C. to 1000° C.

Preferably, boron is implanted at the same selected depth as the implanted hydrogen for lowering the thermal energy required to split the growth substrate.

Advantageously, at least one layer of material is provided on the surface of the thin film functional material.

Preferably, the layer material comprises a buffer material having a low index of refraction.

Alternatively, the layer material comprises at least one metal. Preferably, the layer material comprises chrome and one of gold and silver, about a 10 nm layer of the chrome is deposited on the thin film functional material; and about a 700 nm layer of the one of gold and silver is deposited on the chrome layer.

Preferably, a conductive connection is provided between the GaAs or CMOS circuitry and the surface of the second substrate; at least one metal layer is provided on the surface of the thin film functional material, and the conductive connection and the at least one layer are conductively attached to each other during or after the bonding step.

Advantageously, a conductive connection is provided between the GaAs or CMOS circuitry and the surface of the second substrate; at least one metal layer is provided on the surface of the thin film functional material; and at least one metal layer is provided on the surface of the second substrate, and the at least one layer on the thin film functional material and the layer on the second substrate are conductively attached to each other during or after the bonding step.

In an alternative embodiment, the film layer of thin film functional material is grown directly on the surface of the growth substrate.

Yet another embodiment for fabricating an optimized device comprises the steps of: depositing at least one protective layer on one surface of a growth substrate; growing a film layer of thin film functional material on the at least one protective layer, said functional material comprising a material selected from the group consisting of photoelectric, piezoelectric, pyroelectric, electro-optical, wave guide, nonlinear optical, photorefractive, and wide band gap materials; implanting hydrogen to a selected depth within the growth substrate or within the at least one protective layer to form a hydrogen ion layer so as to divide the material having the growth substrate and the at least one protective layer into distinct portions; bonding the growth substrate including the at least one protective layer and the thin film layer to an optimized substrate; splitting the material having the growth substrate and the at least one protective layer along the implanted ion layer and removing the portion of the material which is on the side of the ion layer away from the optimized substrate.

Preferably, the optimized substrate comprises a material selected from a group consisting of comprised of glass, quartz, poly-SiC, semi-insulating GaAs, diamond, or sapphire.

Advantageously, the thin film functional material is comprised of a material selected from a group consisting of PZT, SrBaTiO₃, PLZT, LiNbO₂, SiGe, GaAs, CdTe/HgCdTe, ZnO and GaN.

Preferably, at least one layer of material is provided on the surface of the thin film functional material.

Advantageously, the layer material comprising a buffer material having a low index of refraction.

Alternatively, the layer material is comprised of at least one metal. Preferably, the layer material comprises chrome and one of gold and silver, about a 10 nm layer of the chrome is deposited on the thin film functional material; and about a 700 nm layer of the one of gold and silver is deposited on the chrome layer.

Advantageously, the growth substrate further comprises glass, the at least one metal substrate is anodically bonded to the glass substrate, and about a 50 nm layer of a material selected from the group consisting of chrome, titanium and aluminum is deposited on the gold or silver layer.

In an alternative embodiment, the thin film functional material is grown on the surface of the growth substrate.

The method herein overcomes many problems of the prior art because thin film protective materials can be grown on a large diameter substrate at an optimized temperature of 500° C. to 1000° C. with smooth separation from the substrate and smooth transfer to atop an appropriate substrate for use.

Other features and advantages of the invention will be set forth in, or will be apparent from, the detailed description of a preferred embodiment, which follows.

### BRIEF DESCRIPTION OF THE DRAWINGS

FIG. 1a is a schematic side elevational view illustrating a step in a first preferred embodiment of the method of the invention.

FIG. 1b is a schematic side elevational view of a finished product resulting from the method of the embodiment of FIG. 1a.

FIG. 2a is a schematic side elevational view illustrating a step in a preferred embodiment of the method of the invention.

FIG. 2b is a schematic side elevational view of a finished product resulting from the method of the embodiment of FIG. 2a.

FIG. 3a is a schematic side elevational view illustrating a step in an embodiment of the method of the invention.

FIG. 3b is a schematic side elevational view of a finished product resulting from the method of the embodiment of FIG. 3a.

FIG. 4 is a schematic side elevational view illustrating an alternative bonding step in an embodiment of the method of the invention.

FIG. 5 is a schematic side elevational view illustrating an alternative step in an embodiment of the method of the invention.

FIG. 6a is a schematic side elevational view illustrating a step in an embodiment of the method of the invention.

FIG. 6b is a schematic side elevational view of a finished product resulting from the method of the embodiment of FIG. 6a.

FIG. 7a is a schematic side elevational view illustrating a step in an embodiment of the method of the invention.

FIG. 7b is a schematic side elevational view of a finished product resulting from the method of the embodiment of FIG. 3a.

### DESCRIPTION OF THE PREFERRED EMBODIMENTS

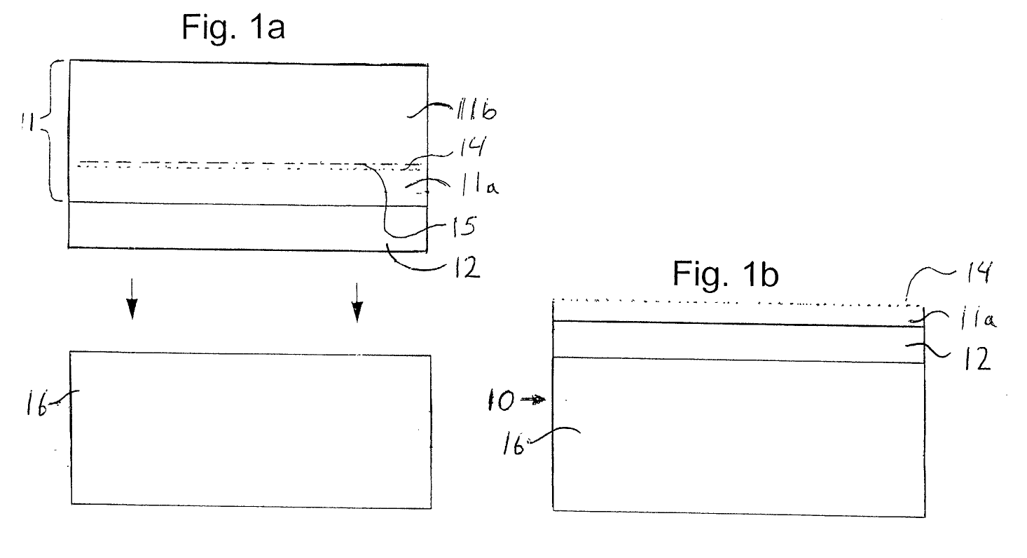

Preferred embodiments of the optimized substrate transfer method will be discussed with reference to the drawings Referring to FIG. 1a, the basic method of thin film layer transfer is illustrated. The fabrication process begins with a large diameter growth substrate 11, as the term “large diameter” is understood within the art. The growth substrate 11 is often comprised of silicon, GaAs, sapphire, quartz or similar material. Of these potential growth substrate materials, the material of the most interest is silicon because large diameter silicon substrates can readily be obtained from silicon at low cost.

A thin film 12 of thin film functional material is grown directly on the growth substrate 11. Some thin film material layers such as SiGe, GaAs, and CdTe/HgCdTe can be grown directly on a silicon substrate without the need for a buffer layer Further, zinc oxide or GaN thin film functional materials can be grown directly on a sapphire or SiC growth substrate and transferred to a substrate optimized for normal conductivity or microwave insulating properties.

The thin film 12 can be grown upon the growth substrate using conventional methods such as sputter deposition, pulse laser deposition, sol gel techniques, MOCVD, MBE, CVD, and other suitable methods. After being grown, the thin film 12 can be annealed at 600° C. to 1000° C. for strengthening and tempering.

A hydrogen ion implant operation is next carried out. A hydrogen ion splitting layer 14, i.e. the peak of the hydrogen implant, is implanted, within the growth substrate 11. The first substrate is divided into portions 11a and 11b.

At this juncture, the large diameter growth substrate 11 is bonded to a second substrate 16 shown at the bottom of FIG. 1a. It is to be understood generally in the embodiments herein that the second substrate 16 can be either a semiconductor substrate having CMOS or GaAs circuitry or an optimized substrate, as discussed herein. In this embodiment, the second substrate is an optimized substrate.

There are numerous methods available for carrying out the bonding. These bonding methods include conductive polymer adhesive bonding, organic adhesive bonding, reaction bonding, fit glass bonding, brazing, thermal compression bonding, ultrasonic bonding, vacuum bonding, anodic bonding, epoxy bonding, Au eutectic bonding, Ni eutectic bonding, direct bonding, and bump bonding.

Advantageously, the surface of the optimized substrate 16 to be bonded can be planarized before bonding using chemical-mechanical polishing to provide a smooth surface for improved bonding of the thin film material 12 to the surface of the optimized substrate 16. Alternatively, pedestals (not shown) may be provided on the surface of the optimized substrate.

After the bonding step is completed, hydrogen layer splitting is carried out at the splitting layer or ion implant peak 14, resulting in the separation of growth substrate part 11b from the remainder of the growth substrate 11a. Hydrogen layer splitting can be performed preferably by using one of two conventional methods. The first method involves heating. Such heating causes the hydrogen within the layer to expand and the expansion of the hydrogen layer 14 produced splitting of the growth substrate 11, and the separation of substrate portion 11b from the remainder of the substrate 11a.

Hydrogen layer splitting can also be carried out by directing a high pressure gas stream towards the side of the wafer at the location of the hydrogen ion implant layer 14. The growth substrate 11 splits under the pressure of the high pressure gas stream at the location of the hydrogen implant peak or splitting layer 14. This splitting can be achieved even at room temperature. The high pressure method thus can be used with polymer adhesives, which can typically be exposed to a maximum temperature of approximately 150° C. It is noted that there are other bonding materials which can withstand only a low temperature hydrogen layer splitting operation and thus can likewise be used with the high pressure gas initiated hydrogen implant layer splitting. These bonding materials include conductive polymer adhesives, silver paint, graphite paint, epoxy bonding material, soft solders, and indium cold welding material.

If heat is used to initiate the splitting, a lowered temperature for the splitting can be obtained by adding, in addition to the hydrogen implant layer 14, a boron implant layer 15 at the same location as the hydrogen implant layer 14. The boron layer 15, added to the hydrogen layer 14, decreases the splitting temperature of the layers. In FIG. 1a, the boron layer 15 is shown slightly apart from the hydrogen layer 14 for clarity. The lowest splitting temperature demonstrated for silicon is 200° C.-250° C. by using a combination of the hydrogen implant and the boron implant with the peak of both implants at the same location. Optionally deposit material layer 15 and chemical mechanical polish (CMPO polish this material layer to obtain a small surface roughness that is suitable for direct wafer bonding. The material layer to be deposited and CMP polished can include dielectric material, conductive material, metal layer, silicon oxide, silicon nitride, amorphous silicon, polysilicon, etc. Advantageously, the material layer 17 on the top surface of the second substrate 16 to be bonded is planarized before bonding using chemical-mechanical polishing for providing improved bonding.

Referring to FIG. 1b, a product 10 resulting from the steps of this embodiment, viz an optimized substrate with a thin film functional layer, is shown.

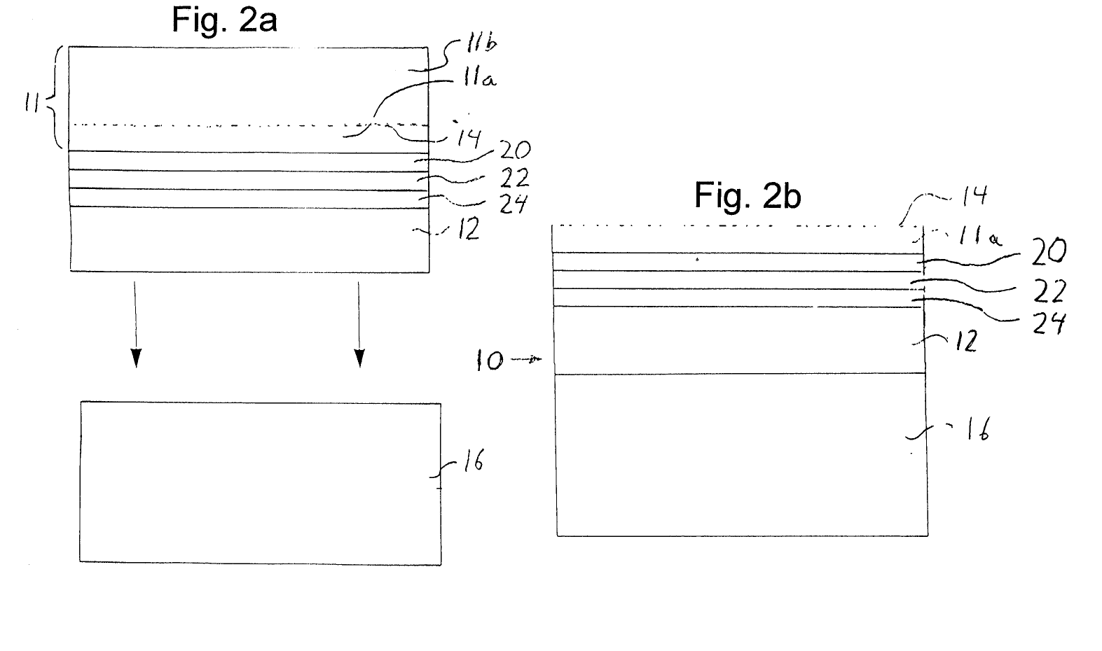

Turning to FIG. 2a, a further embodiment of the thin layer transfer method of FIGS. 1a-1b is shown. Because this embodiment and the remaining embodiments herein are similar to that of FIGS. 1a-1b, corresponding elements have been given the same reference numerals throughout this disclosure.

In this embodiment, silicon is the growth substrate. When silicon is used as the growth substrate material, and as indicated above, silicon is a preferred growth substrate material, some thin film materials such as PZT, PLZT, SrBaTiO₃, and LiNbO₃, typically would not be grown directly on the silicon growth substrate 11 due to the detrimental effects of reactions between the thin film layer 12 with the silicon of grown substrate 11. In such cases, as typified in this embodiment, the thin film layer 12 is grown on a protective layer 24 located between the thin film layer 12 and growth substrate 16. Protective layer 24 preferably comprises a platinum layer or iridium layer.

An oxide layer 20 is grown on the silicon substrate 11. An adhesion layer 22, preferably titanium containing adhesion layer, is deposited on the oxide layer 20. The platinum or iridium layer 24 is deposited on the titanium adhesion layer 22. The oxide layer 20 insulates the silicon substrate 11, and the adhesion layer 22 facilitates bonding between the oxide layer 20 and the protective layer 24.

When a platinum or iridium protective layer 24 is present, the hydrogen implant will pass through the platinum or iridium film 24, the thin film layer 12 and other layers, with the peak of the dose residing in the silicon to create a hydrogen implant splitting layer 14 located within the growth substrate 11. The implant layer 14 is typically placed within the silicon substrate 11 to prevent damage to the protective layers or thin film layer 12 from splitting of the layer to be described herein.

In one non-limiting example, a 250 nanometer thick SrBaTiO₃ ferroelectric film 10 was grown on a 100 nanometer thick platinum layer 24. The platinum layer 24 was grown on a 50 nanometer titanium layer 22. The titanium layer 22 was grown on a 100 nanometer silicon oxide film 20, which, in turn, was grown on a silicon substrate material 16.

In this embodiment, the second substrate is an optimized substrate. If desirable, the remaining silicon material 11a and up to all the protective layers 20, 22, 24 can be etched away after the hydrogen ion layer splitting step, so as to leave only the thin film functional layer 12, or the thin film functional layer 12 and the platinum layer 24, bonded to the optimized substrate 16. In this embodiment, and the remaining embodiments herein, the second substrate 16 is, as discussed heretofore, a silicon or GaAs substrate with CMOS or GaAs circuitry 18.

Referring to FIG. 2b, a product 10 resulting from the steps of this embodiment, viz an optimized substrate with a thin film functional layer, is shown.

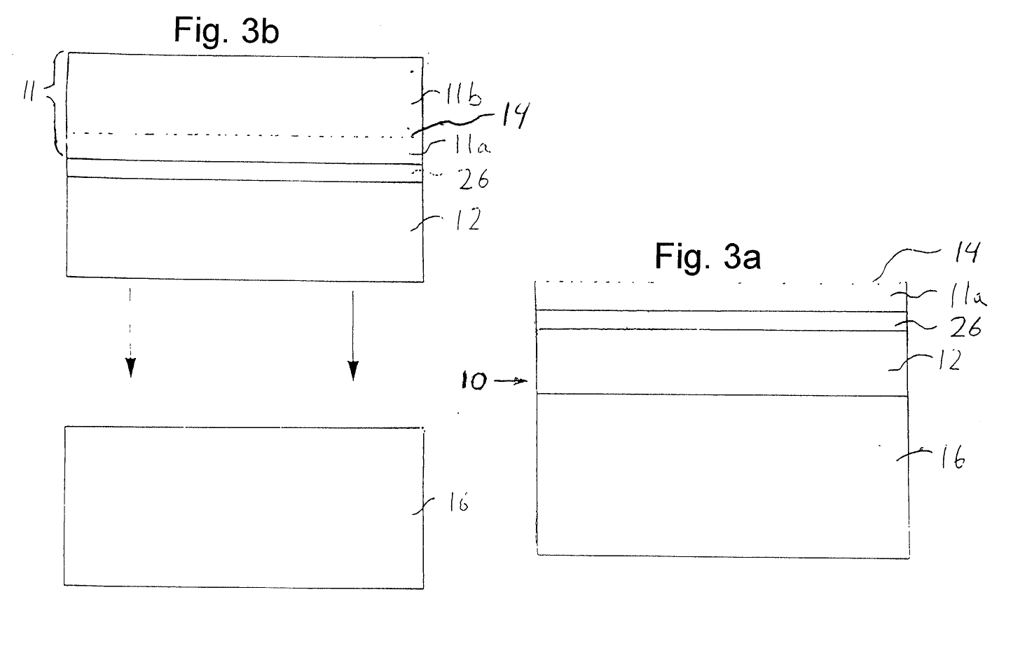

Turning to FIG. 3a, a further embodiment of the thin layer transfer method of FIGS. 1a-1b is shown. An MgO buffer layer 26 is deposited on the growth substrate 11, and the thin film layer 12 is deposited on the MgO layer 26. The MgO layer is used as a buffer layer instead of the platinum or iridium layer 24, adhesive layer 22 and oxide layer 20 shown in the alternative embodiment disclosed herein. If the MgO layer 26 is sufficiently thick, the hydrogen layer 14 can be implanted within the MgO layer 26 instead of the growth substrate 11. In this embodiment, the implant layer 14 is within the growth substrate 11.

Similar to the previous embodiment herein, the protective MgO layer 26 can be etched away, so as to leave only the thin film functional layer 12, bonded to the second substrate 16. In this embodiment, the second substrate 16 is an optimized substrate.

In FIG. 3b, a product 10 resulting from the steps of this embodiment, viz an optimized substrate with a thin film functional layer, is shown.

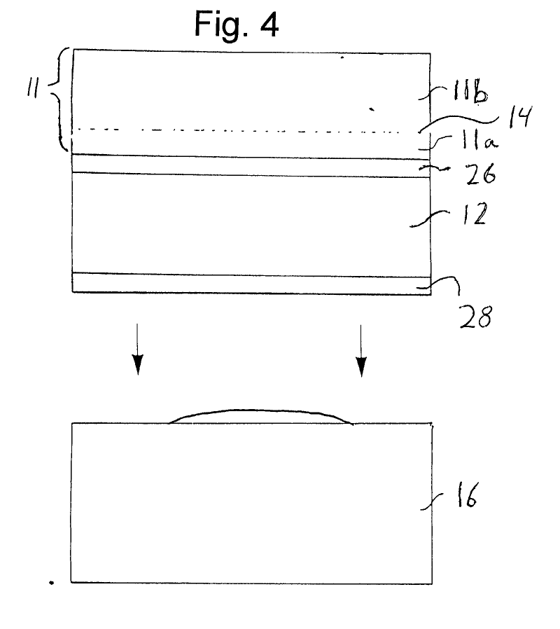

Turning to FIG. 4, there is shown an embodiment that is a modification of the method of the invention. If bump bonding, with the use of a bump bonding material 30, is used to bond the thin film material 12 to the second substrate 16, it is often necessary to provide a thick (often about 25 um) mechanical stiffener material on the surface of the thin film functional layer 12 prior to hydrogen ion implant splitting. The stiffener layer 28 is typically a metal and provides mechanical support to the thin film material 12 so as to protect the thin film material from damage during the splitting process.

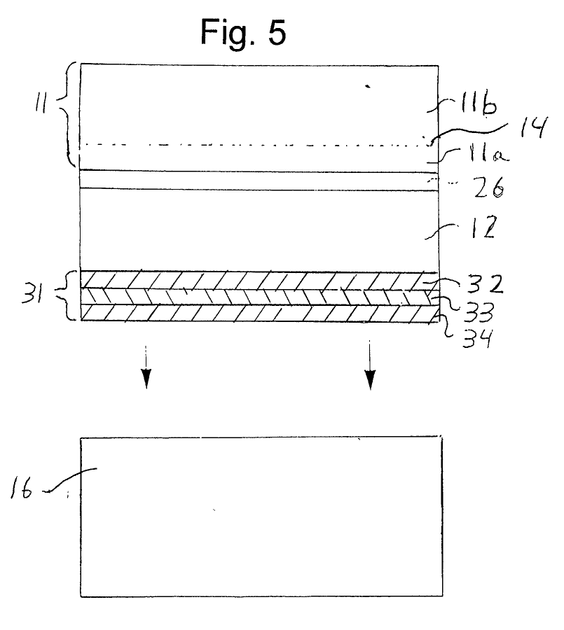

Turning to FIG. 5, there is shown a further embodiment that is a modification of the method of the invention. At least one layer of material 31 is deposited on the bottom of the thin film functional material 12 prior to bonding with the second substrate 16. The addition of the at least one layer of material 31increases the number of possible devices which can be fabricated. The at least one layer of material 31 can be a buffer layer having a low index of refraction. The buffer layer is particularly useful if a device such as an optical modulator or switch is to be fabricated. If a device having an electrode such as a capacitor, optical modulator or optical switch is to be fabricated, then the material of the at least one layer 31 is an electrode typically having a metal or metals, as in this embodiment.

In one non-limiting example, a 10 nm chrome layer 32 is grown on the surface of a SrBaTiO3 thin film functional material layer 12. A 700 nm thick layer of gold or silver layer 33 is grown on the chrome layer 32. If the metal layers 32, 33 are going to be anodically bonded to a glass optimized substrate 16, as in this embodiment, an additional layer comprising 50nm of chrome, titanium or aluminum 34 are deposited on the gold or silver layer 33. The chrome, titanium or aluminum layer 34 will form a surface oxide to which the glass-optimized substrate 16 can anodically bond.

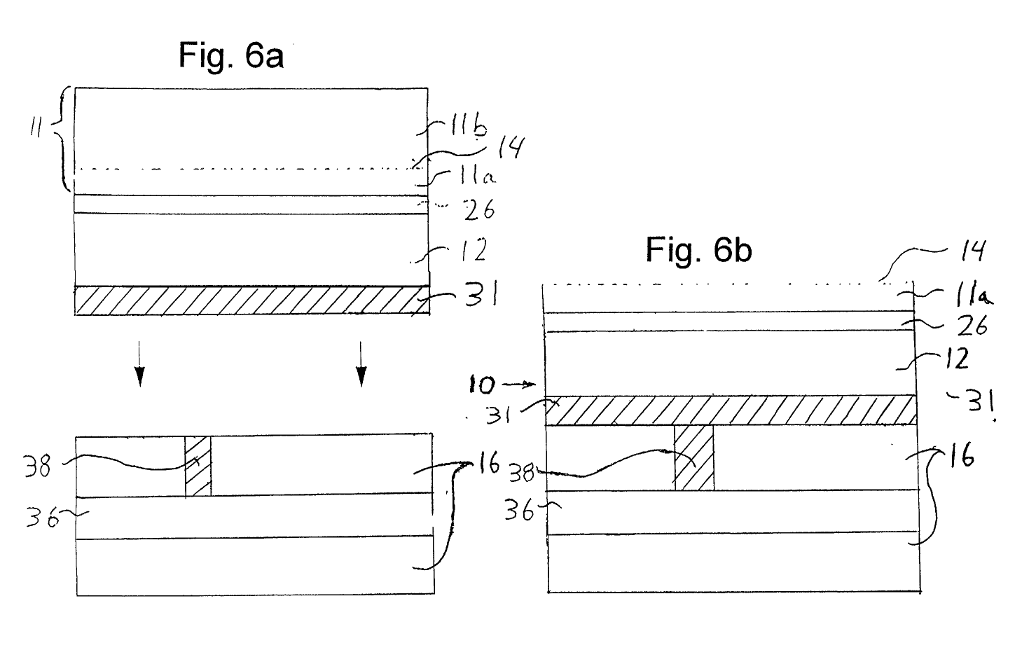

Turning to FIG. 6a, there is shown yet another embodiment which is a modification of the method of the invention. At least one layer of material 31 is provided on the lower surface of the thin film functional layer 12. In this embodiment, the at least one layer 31 provided on the thin film functional material is a metal electrode and the second substrate is a GaAs or silicon substrate having GaAs or CMOS circuitry 36. A conductive connection 38 is provided between the GaAs or CMOS circuitry 36 located within the optimized substrate16 and the surface of the optimized substrate 16. When the thin film functional material 12 and associated layers are bonded to the optimized substrate 16, the metal electrode layer 31 is bonded to the surface of the optimized substrate 16, and the conductive connection 38, thereby forming a conductive connection between the electrode layer 31 and the CMOS or GaAs circuitry 36, so as to allow the fabrication of electrode containing devices.

In FIG. 6b, the product 10 resulting from the steps of the embodiment, viz a semiconductor substrate having a thin film functional material and a connected electrode, is shown.

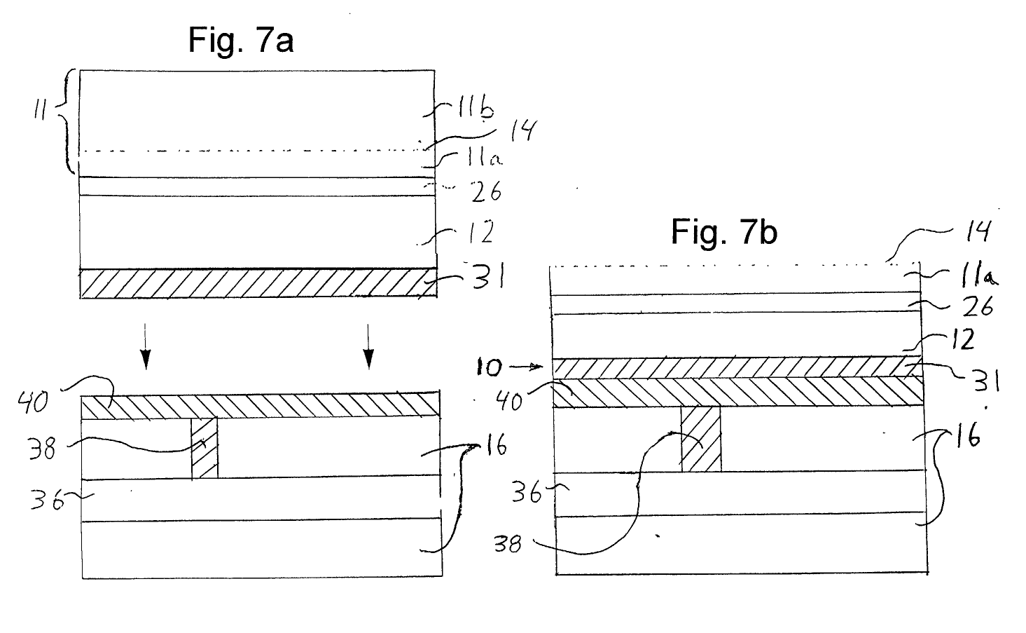

Turning to FIG. 7a, there is shown a further embodiment that is a modification of the method of the invention. If desired, a metal layer 40 is provided on the surface of the optimized substrate 16. The metal layer 40 is bonded to the optimized substrate using suitable techniques within the art, and is in conductive contact with the conductive connection 38 from the GaAs or CMOS circuitry 36. When the thin film functional material 12 and associated layers are bonded to the optimized substrate 16, the metal layer 40 on the surface of the optimized substrate 16 is bonded to the metal layer 31 on the bottom surface of the thin film functional material 12. A conductive connection is formed thereby between the GaAs or CMOS circuitry 36 and the metal layers 31, 40, so as to allow the fabrication of a device with an electrode.

In FIG. 7b, the product 10 resulting from the steps of the embodiment, viz a semiconductor substrate having a thin film functional material and a connected electrode, is shown.

Although the invention has been described above in relation to preferred embodiments thereof, it will be readily understood by those skilled in the art that variations and modifications can be effected without departing from the scope and spirit of the invention.

What is claimed is:

1. A method for making a thin film semiconductor device, said method comprising the steps of:
(a) depositing at least one protective layer on one surface of a growth substrate;
(b) growing a film layer of thin film functional material on the at least one protective layer, said functional material comprising a material selected from the group consisting of photoelectric, piezoelectric, pyroelectric, electro-optical, wave guide, nonlinear optical, photorefractive, and wide band gap materials;
(c) implanting hydrogen to a selected depth within the growth substrate or within the at least one protective layer to form a hydrogen ion layer so as to divide the material having the growth substrate and the at least one protective layer into distinct portions;
(d) bonding the growth substrate including the at least one protective layer and the thin film layer to a second substrate comprising silicon or GaAs and having CMOS or GaAs circuitry;
(e) splitting the material having the growth substrate and the at least one protective layer along the implanted ion layer and removing the portion of the material which is on the side of the ion layer away from the substrate having CMOS or GaAs circuitry.

2. The method according to claim 1, wherein the growth substrate is comprised of a material selected from a group consisting of silicon, GaAs, quartz, and sapphire.

3. The method according to claim 1, the growth substrate comprising silicon.

4. The method according to claim 1, the growth substrate comprising silicon; the at least one protective layer comprising an oxide layer, an adhesion layer, and a barrier layer; and the method further comprising the steps of;
depositing the oxide layer on the silicon substrate;
depositing the adhesion layer on the oxide layer; and
depositing the barrier layer on the adhesion layer for isolating the thin film layer.

5. The method according to claim 4, wherein the adhesion layer is comprised of titanium, and wherein the barrier layer comprises a material selected from a group consisting of platinum and iridium.

6. The method according to claim 1, the at least one protective layer comprising MgO.

7. The method according to claim 1, wherein the thin film functional material is comprised of a material selected from a group consisting of PZT, SrBaTiO₃, PLZT, LiNbO₂, SiGe, GaAs, CdTe/HgCdTe, ZnO and GaN.

8. The method according to claim 1, further comprising the step of;
annealing the thin film functional material layer for strengthening and tempering the thin film layer at a temperature of about 600° C. to 1000° C.

9. The method according to claim 1, further comprising the step of;
implanting boron at the same selected depth as the implanted hydrogen for lowering the thermal energy required to split the growth substrate.

10. The method according to claim 1, further comprising the step of:
providing at least one layer of material on the surface of the thin film functional material.

11. The method according to claim 10, the layer material comprising a buffer material having a low index of refraction.

12. The method according to claim 10, the layer material comprising at least one metal.

13. The method according to claim 12, the layer material comprising chrome and one of gold and silver, the method further comprising the steps of:
depositing about a 10 nm layer of the chrome on the thin film functional material; and
depositing about a 700 nm layer of the one of gold and silver on the chrome layer.

14. The method according to claim 1, further comprising the steps of:
providing a conductive connection between the GaAs or CMOS circuitry and the surface of the second substrate; and
providing at least one metal layer on the surface of the thin film functional material,
wherein the conductive connection and the at least one layer are conductively attached to each other during or after the bonding step.

15. The method according to claim 1, further comprising the step of:
providing a conductive connection between the GaAs or CMOS circuitry and the surface of the second substrate; and
providing at least one metal layer on the surface of the thin film functional material; and
providing at least one metal layer on the surface of the second substrate, wherein the
and the at least one layer on the thin film functional material and the layer on the second substrate are conductively attached to each other during or after the bonding step.

16. A method for making an optimized device, said method comprising the steps of:
(a) depositing at least one protective layer on one surface of a growth substrate;
(b) growing a film layer of thin film functional material on the at least one protective layer, said functional material comprising a material selected from the group consisting of photoelectric, piezoelectric, pyroelectric, electro-optical, wave guide, nonlinear optical, photorefractive, and wide band gap materials;
(c) implanting hydrogen to a selected depth within the growth substrate or within the at least one protective layer to form a hydrogen ion layer so as to divide the material having the growth substrate and the at least one protective layer into distinct portions;
(d) bonding the growth substrate including the at least one protective layer and the thin film layer to an optimized substrate;
(e) splitting the material having the growth substrate and the at least one protective layer along the implanted ion layer and removing the portion of the material which is on the side of the ion layer away from the optimized substrate.

17. The method according to claim 16, wherein the optimized substrate comprises a material selected from a group consisting of comprised of glass, quartz, poly-SiC, semi-insulating GaAs, diamond, or sapphire.

18. The method according to claim 16, wherein the thin film functional material is comprised of a material selected from a group consisting of PZT, SrBaTiO₃, PLZT, LiNbO₂, SiGe, GaAs, CdTe/HgCdTe, ZnO and GaN.

19. The method according to claim 1, further comprising the step of:
providing at least one layer of material on the surface of the thin film functional material.

20. The method according to claim 19, the layer material comprising a buffer material having a low index of refraction.

21. The method according to claim 19, the layer material comprising at least one metal.

22. The method according to claim 21, the layer material comprising chrome and one of gold and silver, the method further comprising the steps of:
depositing about a 10 nm layer of the chrome on the thin film functional material; and
depositing about a 700 nm layer of the one of gold and silver on the chrome layer.

23. The method according to claim 22, wherein the growth substrate further comprises glass and the at least one metal substrate is anodically bonded to the glass substrate, and further comprising the step of:
depositing about a 50 nm layer of a material selected from the group consisting of chrome, titanium and aluminum on the gold or silver layer.

24. A method for making a thin film semiconductor device, said method comprising the steps of:
(a) growing a film layer of thin film functional material on the surface of a growth substrate, said functional material comprising a material selected from the group consisting of photoelectric, piezoelectric, pyroelectric, electro-optical, wave guide, nonlinear optical, photorefractive, and wide band gap materials;
(b) implanting hydrogen to a selected depth within the growth substrate to form a hydrogen ion layer so as to divide the growth substrate into distinct portions;
(c) bonding the growth substrate and associated material having the thin film layer to a second substrate having GaAs or CMOS circuitry;
(d) splitting the material having the growth substrate and thin film material along the implanted ion layer and removing the portion of the material which is on the side of the ion layer away from the substrate having the GaAs or CMOS circuitry.

25. A method for making an optimized device, said method comprising the steps of:
(a) growing a film layer of thin film functional material on the surface of a growth substrate, said functional material comprising a material selected from the group consisting of photoelectric, piezoelectric, pyroelectric, electro-optical, wave guide, nonlinear optical, photorefractive, and wide band gap materials;
(b) implanting hydrogen to a selected depth within the growth substrate to form a hydrogen ion layer so as to divide the growth substrate into distinct portions;
(c) bonding the growth substrate and associated material having the thin film layer to a second optimized substrate;
(d) splitting the material having the growth substrate and thin film material along the implanted ion layer and removing the portion of the material, which is on the side of the ion layer away from the optimized substrate.
